(19) United States
(12) Patent Application Publication
(10) Pub. No.: US 2007/0251821 A1
(43) Pub. Date: Nov. 1, 2007

(54) Soft magnetic target material

(75) Inventors: Akihiko Yanagitani, Himeji-Shi (JP); Yoshikazu Aikawa, Himeji-Shi (JP)

Correspondence Address: THE WEBB LAW FIRM, P.C., 700 KOPPERS BUILDING, 436 SEVENTH AVENUE, PITTSBURGH, PA, 15219, US

(73) Assignee: SANYO SPECIAL STEEL CO., LTD., Himeji-shi (JP)

(21) Appl. No.: 11/786,050

(22) Filed: Apr. 10, 2007

(30) Foreign Application Priority Data
Apr. 14, 2006 (JP) 2006-112504

(51) Int. Cl. C23C 14/00

(52) U.S. Cl. 204/298.13

(57) ABSTRACT

There is disclosed a soft magnetic target material with an improved atmospheric resistance without deterioration of magnetic properties. A soft magnetic target material according to the first aspect comprises a Fe—Co based alloy having a Fe:Co atomic ratio of 100:0 to 20:80, wherein the alloy further comprises one or both of Al and Cr of 0.2 to 5 atom %. In addition, a soft magnetic target material according to the second aspect comprises a Fe—Ni based alloy having a Fe:Ni atomic ratio of 100:0 to 20:80, wherein the alloy further comprises one or both of Al and Cr of 0.2 to 5 atom %. In the soft magnetic target materials according to the first and second aspects, the alloys further comprise one or more selected from a group consisting of B, Nb, Zr, Ta, Hf, Ti and V of not more than 30 atom %.

### CROSS REFERENCE TO RELATED APPLICATION

This application claims priority to Japanese Patent Application No. 112504/2006 filed on Apr. 14, 2006, the disclosure of which is incorporated herein by reference.

### TECHNICAL FIELD

The present invention relates to a Fe—Co based or Fe—Ni based target material for forming a soft magnetic thin film by sputtering method.

### BACKGROUND ART

The recent progress in the magnetic recording technology is remarkable, and the record densities of magnetic record media are being heightened for increasing capacities of drives. In the magnetic record media for the longitudinal magnetic recording systems currently used worldwide, however, an attempt to realize a high record density leads to refined record bits, which require a high coercivity to such an extent that recording cannot be made with the record bits. In view of this, a perpendicular magnetic recording system is under study as a means of solving these problems and improving the record densities.

The perpendicular magnetic recording system is a system in which a magnetization-easy axis is oriented in the direction vertical to a medium surface in the magnetic film of the perpendicular magnetic record medium, and is suitable for high record densities. In addition, as for the perpendicular magnetic recording system, a two-layered record medium has been developed having a magnetic record film layer where the record sensitivity is improved and a soft magnetic film layer. A CoCrPt—SiO₂ based alloy is generally used in the magnetic record film layer.

On the other hand, it is proposed that a soft magnetic film of a Fe—Co—B based alloy is used as a soft magnetic film of a two-layered record medium. For example, as disclosed in Japanese Patent Laid-Open Publication No. 346423/2004, there is proposed a Fe—Co—B based alloy target material in which the diameter of the maximum inscribed circle which can be drawn in a region with no boride phase in a cross-microstructure is equal to 30 μm or less.

Magnetron sputtering method is generally used for the preparation of the aforementioned soft magnetic film. This magnetron sputtering method is a method in which a magnet is disposed behind a target material to leak the magnetic flux onto a surface of the target material for converging plasma in the leaked magnetic flux region, enabling a high-speed coating. Since the magnetron sputtering method has a feature of leaking the magnetic flux on the sputtering surface of the target material, in the case where magnetic permeability of the target material itself is high, it is difficult to form, on the sputtering surface of the target material, the leaked magnetic flux necessary and sufficient for the magnetron sputtering method. In view of this, Japanese Patent Laid-Open Publication No. 346423/2004 is proposed for a demand for reducing the magnetic permeability of the target material itself as much as possible.

However, as the thickness limit of the above target product is approximately 5 mm, a thickness above the limit leads to insufficient leaked magnetic flux generated on the target surface, raising a problem that a normal magnetron sputtering cannot be performed. Further, while a Fe based target material is preferable in view of a demand for a high magnetic flux density in a film made of the target material to be used for a magnetron sputtering, this case has a problem with corrosion resistance and may cause poor film qualities due to an oxidation of the target material or a sputtering defect due to an abnormal electric discharge in the oxidized portion during the sputtering.

### SUMMARY OF THE INVENTION

The inventors have now found that an addition of Al or Cr of 0.2 to 5 atom % into a Fe—Co based alloy or a Fe—Ni based alloy having a high saturation magnetic flux density results in a soft magnetic target material with an improved atmospheric resistance without deteriorating the magnetic properties. Here, “atmospheric resistance” means corrosion resistance under circumstances where a device incorporating electric components is used in a room.

It is therefore an object of the present invention to provide a soft magnetic target material with an improved atmospheric resistance without deteriorating the magnetic properties.

That is, a soft magnetic target material according to the first aspect of the present invention comprises a Fe—Co based alloy having a Fe:Co atomic ratio of 100:0 to 20:80, wherein the alloy further comprises one or both of Al and Cr of 0.2 to 5 atom %.

In addition, a soft magnetic target material according to the second aspect of the present invention comprises a Fe—Ni based alloy having a Fe:Ni atomic ratio of 100:0 to 20:80, wherein the alloy further comprises one or both of Al and Cr of 0.2 to 5 atom %.

### DETAILED DESCRIPTION OF THE INVENTION

Reasons for the compositional limitations in the present invention will be explained in detail hereinafter.

That is, a soft magnetic target material according to the first aspect of the present invention comprises a Fe—Co based alloy having a Fe:Co atomic ratio (at ratio) of 100:0 to 20:80 and a soft magnetic target material according to the second aspect of the present invention comprises a Fe—Ni based alloy having a Fe:Ni atomic ratio (at ratio) of 100:0 to 20:80. The Fe—Co based or Fe—Ni based alloy is used for a perpendicular magnetic record film as an alloy system having a high saturation magnetic flux density. Here, the reason for the above Fe:Co or Fe:Ni atomic ratio range is that a Co or Ni content exceeding 80% to Fe leads to poor magnetic properties. It should be noted that the content of Fe and Co and that of Fe and Ni are respectively a value obtained by subtracting contents of Al, Cr, B or the like to be described later from 100 atom %.

The alloys of the soft magnetic target materials according to the first and second aspects of the present invention further comprise one or both of Al and Cr of 0.2 to 5 atom % (at %), preferably 0.5 to 3 atom %. The one or both of Al and Cr of less than 0.2 atom % leads to an insufficient improvement in atmospheric resistance, while that of more than 5 atom % is not preferable for causing poor magnetic properties.

According to a preferred aspect of the present invention, the alloys of the soft magnetic target materials according to the first and second aspects of the present invention preferably comprises one or more selected from a group of consisting of B, Nb, Zr, Ta, Hf, Ti and V of not more than 30 atom %, more preferably 5 to 20 atom %. B, Nb, Zr, Ta, Hf, Ti and V are components for promoting amorphization of the thin film. The total amount of these additives of more than 30 atom % leads to poor magnetic properties, rendering the upper limit 30 atom %.

The method for molding the soft magnetic target materials of the present invention may be any molding method so long as the soft magnetic target materials can be molded with high densities, and includes HIP, hot press and the like as preferred examples. The method of producing powder to be used for molding the soft magnetic target material may be any method of gas-atomizing, water-atomizing and casting-pulverized powder, and is not limited particularly.

As described above, magnetron sputtering method is generally used for forming soft magnetic films, and the soft magnetic target materials of the present invention can be applied to this method. This magnetron sputtering method is a method in which a magnet is disposed behind a target material to leak the magnetic flux onto a surface of the target material for converging plasma in the leaked magnetic flux region, enabling a high-speed coating. This magnetron sputtering device has a feature that a magnet is disposed behind the target material to trap γ electrons in the vicinity of the target material by the application of a magnetic field, aimed at solving the drawback of bipolar DC glow discharge sputtering devices. Since the γ electron has such an orbit as to be entangled with the lines of magnetic force, the plasma concentrates in the vicinity of the target material to reduce damages to the substrate. In addition, since the moving distance of the γ electron becomes long, it is possible to perform a high-speed sputtering at a low gas pressure.

### EXAMPLES

Examples of the present invention will be in detail explained hereinafter.

As shown in FIG. 1, Fe—Co based alloys or Fe—Ni based alloys were produced by gas-atomizing methods or casting method. The gas-atomizing methods were carried out on condition that the type of gas was an argon gas, the nozzle diameter was 6 mm and the gas pressure was 5 MPa. On the other hand, the casting methods were carried out by melting the alloys in a ceramic vessel (φ200×30L) and then pulverizing the alloys to powders. Powders thus produced were classified into 500 μm or less and each powder was stirred for one hour by a V-type mixer.

Each powder thus produced was filled in an enclosing vessel made of a SC steel having a diameter of 200 mm and a height of 100 mm and was encapsulated with vacuum evacuation at an ultimate vacuum of 10⁻¹ Pa or less, followed by an HIP (hot isostatic pressing) at a temperature of 1173K under a pressure of 150 MPa for a holding time of 5 hours. Next, the resultant molding bodies were machined to provide final shapes to obtain target materials having outer diameters of 180 mm and thicknesses of 3 to 10 mm. Properties of the above target materials are shown in Table 1.

TABLE 1

| | Composition | | | | Evaluation Result | | |
|---|---|---|---|---|---|---|---|
| | | Additive | | | Saturation | | |
| | | Element | | | Magnetic | | |
| | Fe:Co(Fe:Ni) | Content | Al, Cr Additive | Manufacturing | Flux | Atmospheric | |
| No | (at ratio) | (at %) | Content (at %) | Method | Density (T) | Resistance | Remarks |
| 1 | Fe:Co = 100:0 | B: 10 | Al: 1 | powder | 1.62 | ∘ | Examples of |
| 2 | Fe:Co = 20:80 | B: 20 | Al: 1 | powder | 1.54 | ∘ | Present |
| 3 | Fe:Co = 40:60 | B: 30 | Al: 3 | powder | 1.67 | ∘ | Invention |
| 4 | Fe:Co = 60:40 | Nb: 4, Zr: 3 | Al: 5 | powder | 1.77 | ∘ | |
| 5 | Fe:Co = 90:10 | Ta: 5, Zr: 4 | Cr: 0.2 | powder | 1.66 | ∘ | |
| 6 | Fe:Ni = 100:0 | Hf: 4, Ta: 5 | Cr: 1 | powder | 1.59 | ∘ | |
| 7 | Fe:Ni = 20:80 | Ti: 10 | Al: 1 | powder | 1.71 | ∘ | |
| 8 | Fe:Ni = 40:60 | V: 10 | Al: 3 | powder | 1.66 | ∘ | |
| 9 | Fe:Ni = 60:40 | Ta: 10, Zr: 7 | Al: 5 | powder | 1.79 | ∘ | |
| 10 | Fe:Ni = 90:10 | Hf: 8, Ta: 6 | Cr: 0.2 | powder | 1.62 | ∘ | |
| 11 | Fe:Co = 65:35 | B: 10 | Cr: 1 | powder | 1.54 | ∘ | |
| 12 | Fe:Co = 30:70 | B: 20 | Al: 5 | powder | 1.51 | ∘ | |
| 13 | Fe:Co = 40:60 | B: 30 | Cr: 0.2 | powder | 1.49 | ∘ | |
| 14 | Fe:Co = 30:70 | Nb: 4, Zr: 3 | Al: 1 | powder | 1.77 | ∘ | |
| 15 | Fe:Co = 90:10 | Ta: 5, Zr: 4 | Al: 1 | powder | 1.81 | ∘ | |
| 16 | Fe:Ni = 100:0 | Hf: 4, Ta: 5 | Al: 1 | powder | 1.52 | ∘ | |
| 17 | Fe:Ni = 20:80 | Ti: 10 | Al: 0.2 | powder | 1.81 | ∘ | |
| 18 | Fe:Ni = 40:60 | V: 10 | Al: 1 | powder | 1.81 | ∘ | |
| 19 | Fe:Ni = 60:40 | Ta: 10, Zr: 7 | Al: 3 | powder | 1.66 | ∘ | |
| 20 | Fe:Ni = 90:10 | Hf: 8, Ta: 6 | Al: 5 | powder | 1.57 | ∘ | |
| 21 | Fe:Co = 30:70 | Zr: 4, Ti: 8 | Cr: 0.2 | powder | 1.74 | ∘ | |
| 22 | Fe:Co = 90:10 | Nb: 12, Zr: 15 | Cr: 1 | powder | 1.62 | ∘ | |
| 23 | Fe:Ni = 100:0 | Hf: 15, Ti: 10 | Cr: 3 | powder | 1.71 | ∘ | |
| 24 | Fe:Co = 65:35 | no addition | Cr: 5 | powder | 1.81 | ∘ | |
| 25 | Fe:Ni = 60:40 | Ta: 10, Zr: 7 | Al: 0.2 | powder | 1.71 | ∘ | |
| 26 | Fe:Ni = 90:10 | Hf: 8, Ta: 6 | Al: 1 | powder | 1.62 | ∘ | |
| 27 | Fe:Co = 30:70 | Nb: 4, Zr: 3 | Al: 3 | powder | 1.64 | ∘ | |
| 28 | Fe:Ni = 100:0 | Hf: 15, Ti: 10 | Al: 5 | powder | 1.71 | ∘ | |
| 29 | Fe:Co = 65:35 | no addition | Cr: 0.2 | powder | 1.68 | ∘ | |
| 30 | Fe:Co = 30:70 | Nb: 4, Zr: 3 | Cr: 1 | powder | 1.66 | ∘ | |
| 31 | Fe:Co = 30:70 | Nb: 4, Zr: 3 | Cr: 3 | powder | 1.65 | ∘ | |
| 32 | Fe:Co = 30:70 | Nb: 4, Zr: 3 | Cr: 5 | powder | 1.57 | ∘ | |
| 33 | Fe:Co = 30:70 | Nb: 4, Zr: 3 | Al: 1 | casting | 1.72 | ∘ | |
| 34 | Fe:Ni = 60:40 | Ta: 10, Zr: 7 | Al: 3 | casting | 1.56 | ∘ | |
| 35 | Fe:Co = 30:70 | Zr: 4, Ti: 8 | Cr: 0.2 | casting | 1.78 | ∘ | |
| 36 | Fe:Co = 8:92 | Ta: 5, Zr: 4 | Al: 1 | powder | 1.31 | ∘ | Comparative |
| 37 | Fe:Ni = 7:93 | Hf: 4, Ta: 5 | Cr: 1 | powder | 1.29 | ∘ | Examples |
| 38 | Fe:Co = 40:60 | Ta: 32 | Cr: 3 | powder | 1.21 | ∘ | |
| 39 | Fe:Co = 30:70 | Nb: 4, Zr: 30 | Cr: 5 | powder | 1.26 | ∘ | |
| 40 | Fe:Co = 90:10 | Nb: 12, Zr: 20 | Al: 0.2 | powder | 1.21 | ∘ | |
| 41 | Fe:Ni = 100:0 | Hf: 15, Ti: 16 | Al: 1 | powder | 1.01 | ∘ | |
| 42 | Fe:Ni = 20:80 | Zr: 16, Ti: 16 | Al: 3 | powder | 1.19 | ∘ | |
| 43 | Fe:Ni = 40:60 | B: 32 | Al: 5 | powder | 1.17 | ∘ | |
| 44 | Fe:Co = 30:70 | Nb: 4, Zr: 3 | Cr: 0.1 | powder | 1.66 | x | |
| 45 | Fe:Co = 30:70 | Zr: 4, Ti: 8 | Al: 0.1 | powder | 1.65 | x | |
| 46 | Fe:Co = 30:70 | Nb: 12, Zr: 15 | Cr: 6 | powder | 1.21 | ∘ | |
| 47 | Fe:Co = 30:70 | Hf: 15, Ti: 10 | Al: 6 | powder | 1.01 | ∘ | |

Note:
The underlined portions fall outside the condition in the present invention.

In order to evaluate properties of the produced target materials, atmospheric resistance test (accelerating test) and a measurement of magnetic properties (saturation magnetic flux density) were conducted as follows.

(1) Atmospheric Resistance Test (Accelerating Test)

Salt spray test using target materials were conducted according to JIS Z 2371 to visually evaluate presence or absence of rusts formed in external appearances of the target materials after sprayed with a 5 wt % NaCl solution for 24 hours. The evaluation was made according to the following criteria.

◯: No formation of rusts.

Δ: Part of the target material rusted.

x: The entire surface of the target material rusted.

(2) Measurement of Magnetic Properties (Saturation Magnetic Flux Density).

Production of a ring test piece: an outer diameter of 15 mm, an inner diameter of 10 mm and a height of 5 mm.

Device: BH tracer.

Applied magnetic field: 8kA/m.

As shown in Table 1, No. 1 to No. 35 are examples of the present invention and No. 36 to No. 47 are comparative examples. Comparative examples No. 36 and No. 37 are low in Fe content and high in Co and Ni content and therefore, the saturation magnetic flux density as a magnetic property is low. Comparative example No. 38 is high in Ta content and therefore, the saturation magnetic flux density is low. Comparative examples No. 39 and No. 40 are high in total Nb and Zr content and therefore, the saturation magnetic flux density is low. Comparative example No. 41 is high in total Hf and Ta content and therefore, the saturation magnetic flux density is low. Comparative example No. 42 is high in total Zr and Ti content and therefore, the saturation magnetic flux density is low. Comparative example No. 43 is high in B content and therefore, the saturation magnetic flux density is low.

Comparative example No. 44 is low in Cr content and therefore, the atmospheric resistance is poor. Comparative example No. 45 is low in Al content and therefore, the atmospheric resistance is poor. Comparative example No. 46 is high in Cr content and therefore, the saturation magnetic flux density is low. Comparative example No. 47 is high in Al content and therefore, the saturation magnetic flux density is low. In contrast, it is found out that since any of Examples No. 1 to 35 of the present invention meets the conditions of the present invention, the saturation magnetic flux density and the atmospheric resistance are superior.

As described above, an addition of one or both of Al and Cr of 0.2 to 5 atom % into a Fe—Co based or Fe—Ni based alloy having a high saturation-magnetic flux density enables a production of a soft magnetic target material with an improved atmospheric resistance without deteriorating magnetic properties, so that this soft magnetic target material can exhibit a sufficient corrosion resistance under circumstances where a device incorporating electric components is used in a room.

1. A soft magnetic target material comprising a Fe—Co based alloy having a Fe:Co atomic ratio of 100:0 to 20:80, wherein the alloy further comprises one or both of Al and Cr of 0.2 to 5 atom %.

2. The soft magnetic target material according claim 1, wherein the alloy further comprises one or more selected from a group consisting of B, Nb, Zr, Ta, Hf, Ti and V of not more than 30 atom %.

3. A soft magnetic target material comprising a Fe—Ni based alloy having a Fe:Ni atomic ratio of 100:0 to 20:80, wherein the alloy further comprises one or both of Al and Cr of 0.2 to 5 atom %.

4. The soft magnetic target material according claim 3, wherein the alloy further comprises one or more selected from a group consisting of B, Nb, Zr, Ta, Hf, Ti and V of not more than 30 atom %.
